(19) United States
(12) Patent Application Publication
(10) Pub. No.: US 2025/0194038 A1
(43) Pub. Date: Jun. 12, 2025

(54) SUPPORT STRUCTURE AND ELECTRONIC APPARATUS

(71) Applicant: Lenovo (Singapore) Pte. Ltd., Singapore (SG)

(72) Inventors: Fumitake Mizoguchi, Kanagawa (JP); Yoshiyuki Shibayama, Kanagawa (JP); Tatsuya Ushioda, Kanagawa (JP); Osamu Yamamoto, Kanagawa (JP)

(73) Assignee: Lenovo (Singapore) Pte. Ltd., Singapore (SG)

(21) Appl. No.: 18/919,224

(22) Filed: Oct. 17, 2024

(30) Foreign Application Priority Data
Dec. 6, 2023 (JP) 2023-206279

(51) Int. Cl. H05K 7/14; H05K 7/12

(52) U.S. Cl. CPC H05K 7/1405; H05K 7/12; H05K 7/1407

(57) ABSTRACT

A support structure supports, on a circuit board, one end of an electronic module having the other end connected to a connector mounted on the circuit board. The support structure includes: a stud member having a flange fixed to a surface of the circuit board, and a cylindrical body which has a screw hole formed therein and which rises from the flange; a screw capable of supporting the other end of the electronic module by being screwed into the screw hole; and a metal capture member having a stud connection part connected to the stud member, a screw holding part that holds the screw in a relatively rotatable state, and an elastically deformable arm part that connects the stud connection part and the screw holding part.

### CROSS-REFERENCE TO RELATED APPLICATIONS

This application claims priority to Japanese Patent Application No. 2023-206279 filed on Dec. 6, 2023, the contents of which are hereby incorporated herein by reference in their entirety.

### BACKGROUND OF THE INVENTION

### Field of the Invention

The present invention relates to a support structure that supports an electronic module on a circuit board, and to an electronic apparatus provided with the support structure.

### Description of the Related Art

An electronic apparatus such as a laptop PC uses an electronic module such as an SSD connected to a connector of a circuit board (motherboard) on which a CPU is mounted (refer to, for example, Japanese Unexamined Patent Application Publication No. 2020-057737).

### SUMMARY OF THE INVENTION

As described in Japanese Unexamined Patent Application Publication No. 2020-057737, normally, one end of an electronic module is connected to a connector mounted on a circuit board, and the other end thereof is supported on the circuit board by a screw. Meanwhile, electronic modules are installed by workers at a factory or the like, and sometimes replaced by users themselves. In such cases, the screws may fall into chassis and may require time and effort to retrieve, or may be lost, thus deteriorating workability of the operation of attaching and detaching electronic modules.

One or more embodiments of the present invention provide a support structure that makes it possible to improve the workability of the operation of attaching and detaching an electronic module, and an electronic apparatus provided with the support structure.

A support structure according to a first aspect of the present invention is a support structure supporting, on a circuit board, one end of an electronic module having the other end connected to a connector mounted on the circuit board, the support structure including: a stud member having a flange fixed to a surface of the circuit board, and a cylindrical body which has a screw hole formed therein and which rises from the flange; a screw capable of supporting the other end of the electronic module by being screwed into the screw hole; and a metal capture member having a stud connection part connected to the stud member, a screw holding part that holds the screw in a relatively rotatable state, and an elastically deformable arm part that connects the stud connection part and the screw holding part.

An electronic apparatus according to a second aspect of the present invention includes: a circuit board having a connector mounted thereon; an electronic module having one end thereof connected to the connector; and a support structure that supports, on the circuit board, the other end of the electronic module, wherein the support structure has: a stud member that has a flange fixed to a surface of the circuit board, and a cylindrical body that has a screw hole formed therein and rises from the flange; a screw capable of supporting the other end of the electronic module by being screwed into the screw hole; and a metal capture member having a stud connection part connected to the stud member, a screw holding part that holds the screw in a relatively rotatable state, and an elastically deformable arm part that connects the stud connection part and the screw holding part.

According to the above-described aspects of the present invention, the workability of the operation of attaching and detaching an electronic module can be improved.

### BRIEF DESCRIPTION OF THE DRAWINGS

FIG. 1 is an electronic apparatus according to an embodiment viewed from above.

FIG. 2 is a plan view schematically illustrating the structure inside a chassis.

FIG. 3A is an exploded perspective view of a support structure.

FIG. 3B is a perspective view of the support structure.

FIG. 3C is a perspective view illustrating an electronic module supported by the support structure.

FIG. 4A is a schematic side sectional view illustrating the electronic module supported by the support structure.

FIG. 4B is a side sectional view in which a screw has been loosened from the state illustrated in FIG. 4A.

FIG. 4C is a side sectional view in which the screw has been removed from the state illustrated in FIG. 4B.

FIG. 5 is an exploded perspective view of a support structure according to a first modified example.

FIG. 6A is a perspective view illustrating a state immediately before an electronic module is supported by the support structure illustrated in FIG. 5.

FIG. 6B is a perspective view illustrating a state in which the electronic module is being supported by the support structure illustrated in FIG. 5.

FIG. 7 is a schematic side sectional view illustrating a state in which the electronic module is being supported by the support structure illustrated in FIG. 5.

FIG. 8 is an exploded perspective view of a support structure according to a second modified example.

FIG. 9A is a perspective view illustrating a state immediately before an electronic module is supported by the support structure illustrated in FIG. 8.

FIG. 9B is a perspective view illustrating a state in which the electronic module is being supported by the support structure illustrated in FIG. 8.

FIG. 10 is a schematic side sectional view illustrating a state in which the electronic module is being supported by the support structure illustrated in FIG. 8.

FIG. 11A is an exploded perspective view of a support structure according to a third modified example.

FIG. 11B is a perspective view illustrating a state in which a capture member illustrated in FIG. 11A has been inserted onto a cylindrical body.

FIG. 11C is a perspective view illustrating a state in which the capture member illustrated in FIG. 11B has been rotated.

FIG. 12A is a plan view illustrating a state in which the capture member illustrated in FIG. 11A has been inserted onto the cylindrical body.

FIG. 12B is a plan view illustrating a state in which the capture member illustrated in FIG. 12A has been rotated.

FIG. 13A is a perspective view illustrating a state immediately before an electronic module is supported by a support structure according to a fourth modified example.

FIG. 13B is a perspective view illustrating a state in which the electronic module is being supported by the support structure illustrated in FIG. 13A.

### DETAILED DESCRIPTION OF THE INVENTION

Hereinafter, embodiments of an electronic apparatus and a support structure according to the present invention will be described in detail with reference to the accompanying drawings.

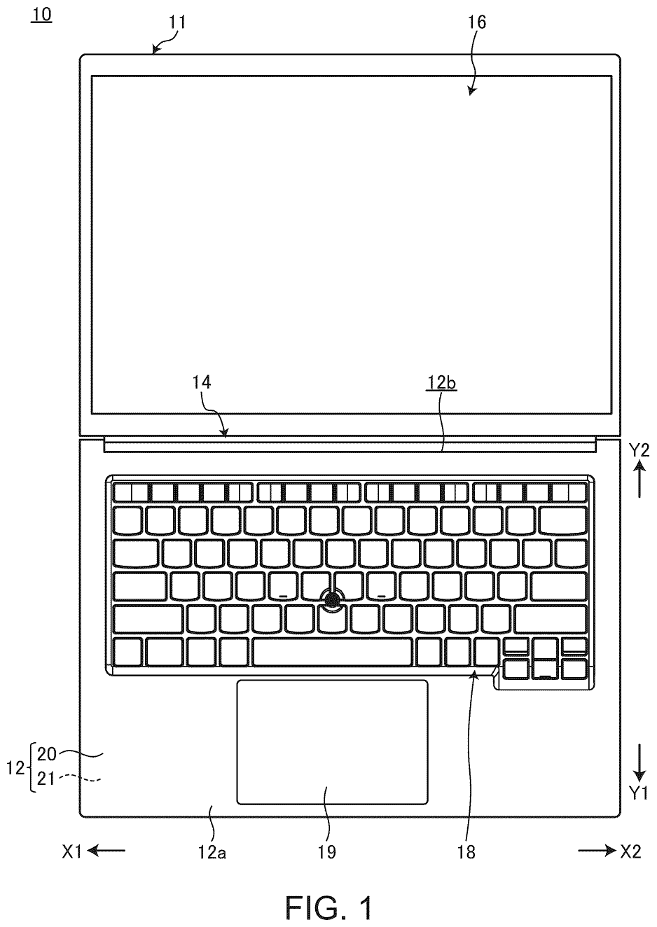

FIG. 1 illustrates an electronic apparatus 10 according to an embodiment observed from above. As illustrated in FIG. 1, the electronic apparatus 10 of the present embodiment is a clamshell laptop PC. The electronic apparatus 10 has a configuration in which a cover body 11 and a chassis 12 are connected by a hinge 14 in a relatively rotatable manner. Although the present embodiment illustrates the electronic apparatus 10 as a laptop PC, the electronic apparatus may alternatively be, for example, a desktop PC, a tablet PC, a smartphone, or a portable game machine other than the laptop PC.

The cover body 11 has a thin, flat, box-shaped chassis. The cover body 11 is provided with a display 16. The display 16 is, for example, an organic EL display or a liquid crystal display.

The chassis 12 is a thin, flat box body. A keyboard device 18 and a touchpad 19 are exposed on the upper surface (a surface 12a) of the chassis 12. Hereinafter, the chassis 12 and the components mounted thereon will be described using the posture of an operator operating the keyboard device 18 as the reference, with the width direction (left and right) of the chassis 12 being referred to as X1 and X2 directions, the depth direction (front and rear) of the chassis 12 being referred to as Y1 and Y2 directions, and the thickness direction (top and bottom) of the chassis 12 being referred to as Z1 and Z2 directions. The X1 and X2 directions may be collectively referred to as the X-direction, and similarly, Y1, Y2 directions and Z1, Z2 directions may be referred to as the Y-direction and the Z-direction, respectively. These directions are defined for the convenience of explanation, and may of course change, depending on the usage state, the installation attitude, or the like of the electronic apparatus 10.

The chassis 12 has a first cover member 20 and a second cover member 21, which are overlapped in the thickness direction and detachably connected with each other. The first cover member 20 forms, for example, the upper surface and the four peripheral side surfaces of the chassis 12, and has a substantially bathtub shape. The second cover member 21 forms, for example, the lower surface of the chassis 12, and has a substantially flat plate shape. The hinge 14 is installed in a concave hinge placement groove 12b formed at the rear edge of the chassis 12 to connect the chassis 12 and the cover body 11.

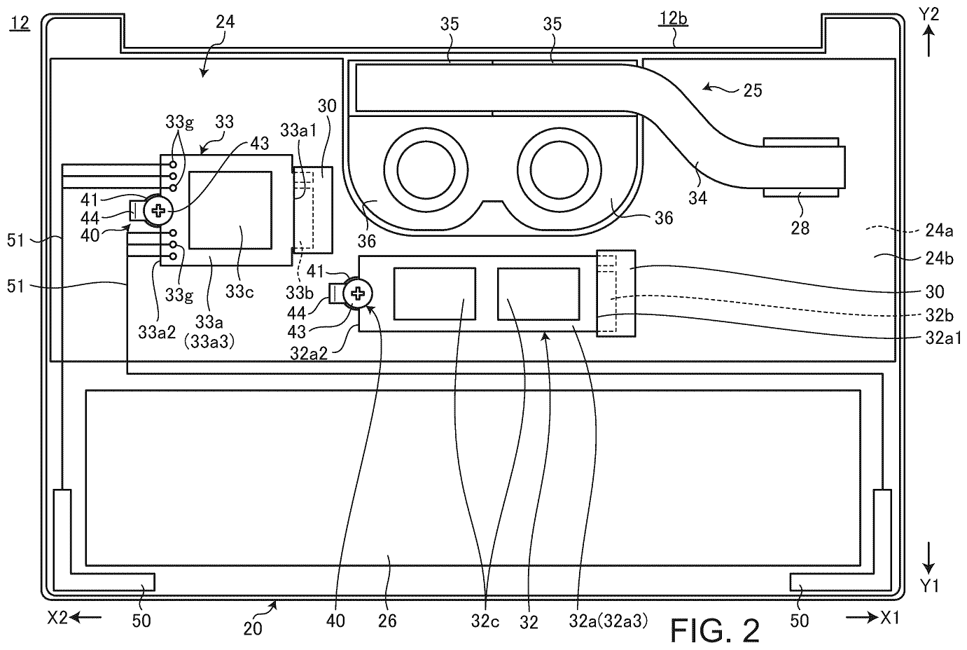

FIG. 2 is a plan view schematically illustrating the internal structure of the chassis 12. FIG. 2 illustrates the inside of the first cover member 20 viewed from the lower surface, with the second cover member 21 having been removed.

As illustrated in FIG. 2, the chassis 12 includes therein a circuit board 24, a cooling module 25, and a battery unit 26. In addition, various electronic components, mechanical components, and the like are provided inside the chassis 12.

The circuit board 24 is a printed circuit board, which is a motherboard of the electronic apparatus 10. The circuit board 24 is placed closer to a Y2 side of the chassis 12 and extends in an X-direction. The circuit board 24 has a CPU (Central Processing Unit) 28 and a pair of connectors 30, 30 mounted thereon. The CPU 28 is a processing device that performs calculations related to the main control of the electronic apparatus 10 and processing therein. The connectors 30 comply with a predetermined connection standard, namely, the M.2 standard, in the present embodiment. Electronic modules 32, 33 are connected to the connectors 30. The specific configurations of the circuit board 24, the electronic modules 32, 33, and the peripheral components thereof will be described later. Various additional electronic components such as a GPU (Graphics Processing Unit) and memories can be mounted on the circuit board 24. In the circuit board 24, for example, the surface on a Z1 side (a first surface 24a) is an installation surface for the first cover member 20, and the surface on a Z2 side (a second surface 24b) is a mounting surface for the CPU 28 and the connectors 30. Needless to say, the shape and the placement of the circuit board 24, and the electronic components and the like to be mounted thereon are not limited to those mentioned above.

The cooling module 25 can absorb heat generated by the CPU 28 and discharge the absorbed heat to the outside of the chassis 12. The cooling module 25 includes a heat pipe 34, a pair of heat sinks 35, 35, and a pair of fans 36, 36. The cooling module 25 can transport the heat from the CPU 28 to the heat sinks 35 through the heat pipe 34, and expedite heat dissipation from the heat sinks 35 by the blast from the fans 36.

The battery unit 26 is a rechargeable battery providing the power source for the electronic apparatus 10. The battery unit 26 is placed closer to a Y1 side relative to the circuit board 24 and extends in the X-direction.

A description will now be given of the specific configuration examples of the circuit board 24 and the electronic modules 32, 33.

First, the circuit board 24 is a printed circuit board having a predetermined conductive pattern formed on the second surface 24b of an insulating plate material. The circuit board 24 may alternatively have a configuration in which conductive patterns are formed on both surfaces 24a, 24b.

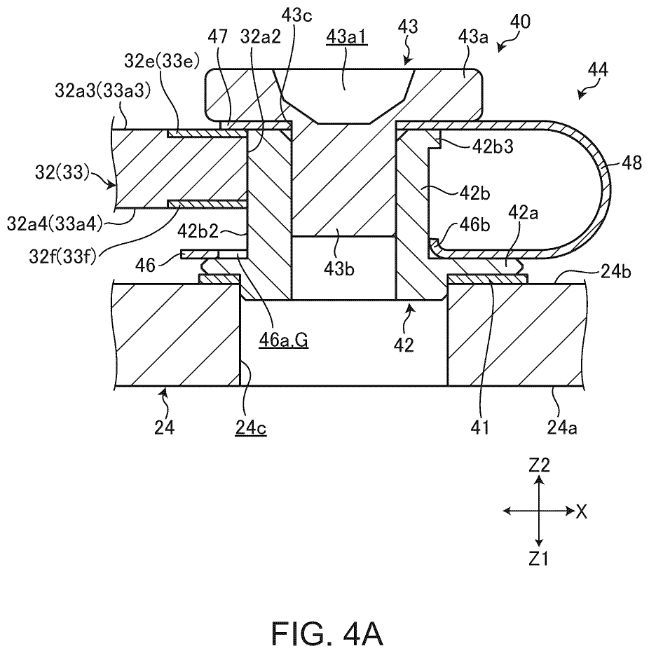

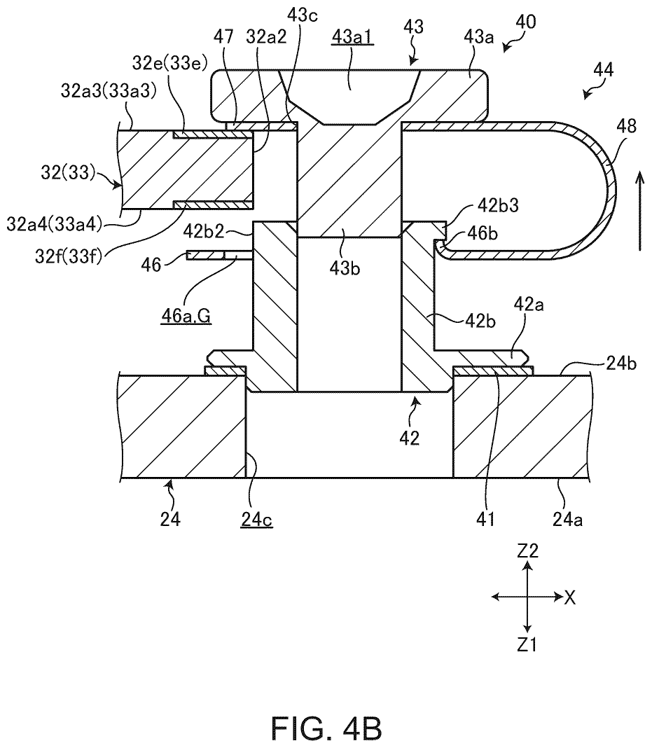

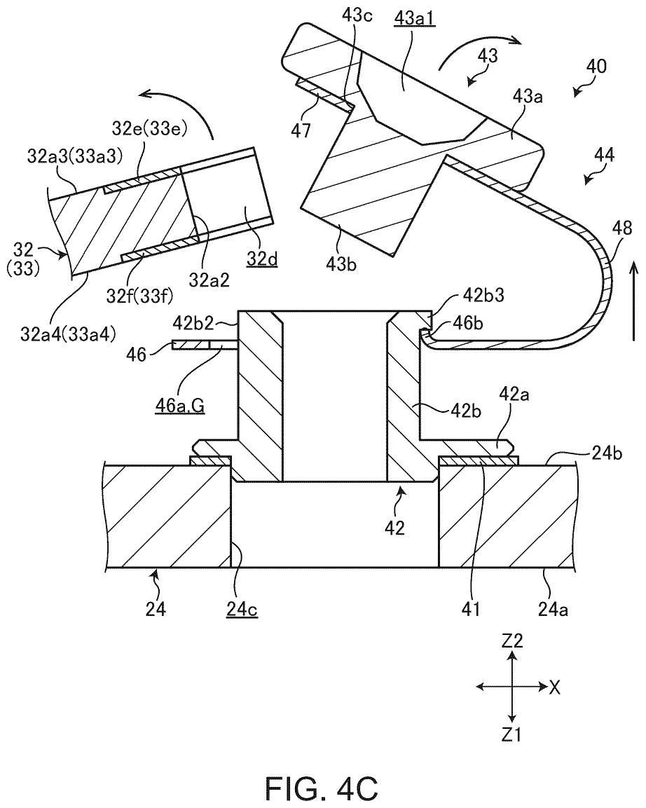

As illustrated in FIG. 2, the circuit board 24 includes the pair of connectors 30, 30 and a pair of support structures 40, 40. The connectors 30 and the support structures 40 together support the electronic modules 32, 33. The second surface 24b of the circuit board 24 is provided with a pair of ground pads 41, 41 used to fix the support structures 40 (refer to FIG. 2 and FIG. 4A). Each of the ground pads 41 is formed of, for example, a metal pattern having a substantially D-shape formed by cutting a part of a circle. The metal pattern is, for example, copper foil printed by a silk screen process. The circuit board 24 has, for example, a through hole 24c, and the ground pads 41 are formed on the periphery thereof adjacent to the second surface 24b.

The connectors 30 are mounted on the second surface 24b. Although the implementation type of the connectors 30 is not limited, a drop-in implementation type (PCIe Gen3: PCI Express 3.0) or an on-board implementation type (PCIe Gen4: PCI Express 4.0), for example, can be used.

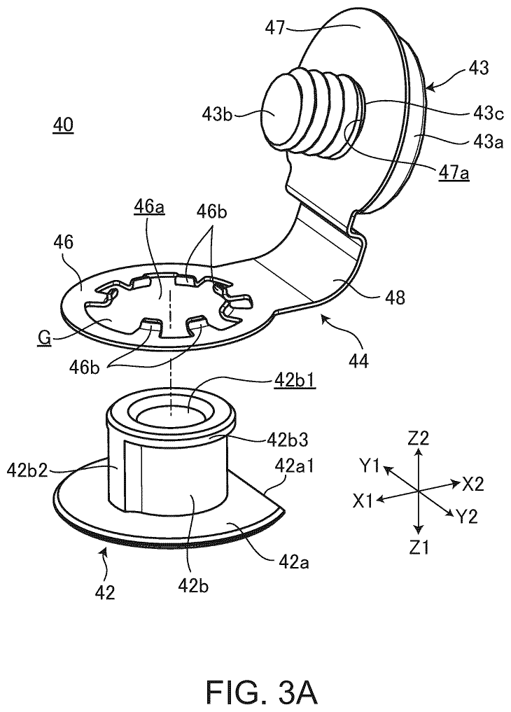

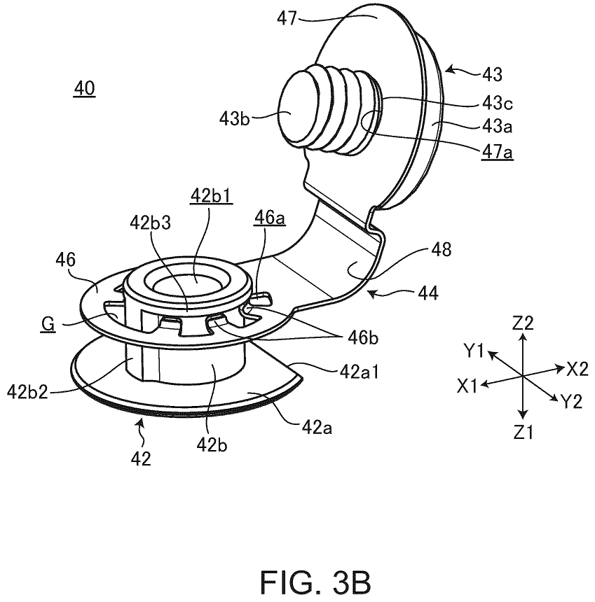

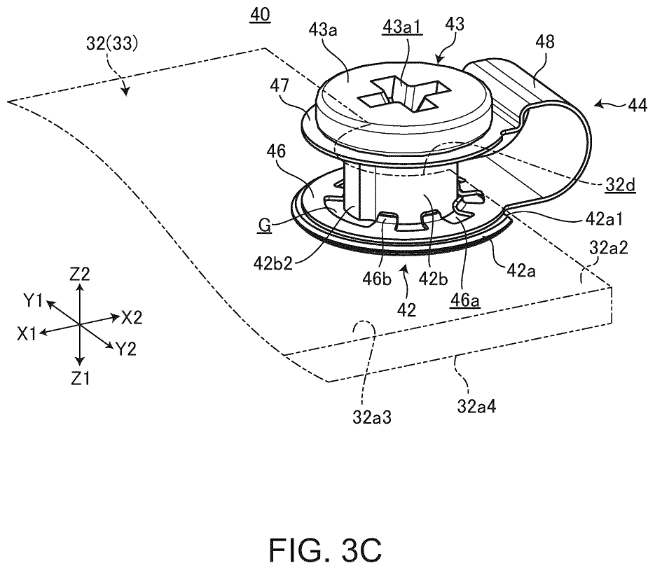

FIG. 3A is an exploded perspective view of the support structure 40. FIG. 3B is a perspective view of the support structure 40. FIG. 3C is a perspective view illustrating a state in which the electronic module 32 is being supported by the support structure 40. FIG. 4A is a schematic side sectional view illustrating a state in which the electronic module 32 is being supported by the support structure 40. FIG. 4B is a side sectional view illustrating a screw 43 that has been loosened from the state illustrated in FIG. 4A. FIG. 4C is a side sectional view illustrating the screw 43 having been removed from the state illustrated in FIG. 4B. Here, a configuration in which one electronic module 32 is supported by the support structure 40 will be representatively described, but a configuration in which the other electronic module 33 is supported by the support structure 40 can be the same as or similar to this configuration.

As illustrated in FIG. 3A to FIG. 4C, the support structure 40 includes a stud member 42, the screw 43, and a capture member 44. The support structure 40 fastens the screw 43 to the stud member 42 fixed to the circuit board 24 so as to support the electronic module 32 (33) on the electronic module 32 (33).

The stud member 42 is a metal component having a flange 42a and a cylindrical body 42b.

The flange 42a is a metal disk having a shape obtained by cutting a part of a circle along a cut surface 42a1. Consequently, the flange 42a has a substantially D-shape in plan view. The cylindrical body 42b is a cylinder which is formed integrally with the flange 42a and which rises in a Z-direction from the center of the flange 42a. The inner circumferential surface of the cylindrical body 42b is provided with a screw hole 42b1 having a female thread formed therein. The outer circumferential surface of the cylindrical body 42b is provided with a stopper portion 42b2 on the opposite side from the cut surface 42a1 in the diameter direction. The stopper portion 42b2 is a rib extending along an axial direction (the Z-direction) of the cylindrical body 42b. A flange-shaped enlarged diameter portion 42b3 having a diameter that is larger than the diameters of the other outer circumferential surfaces is provided at the top edge of the cylindrical body 42b.

The surface of the flange 42a on the Z1 side is fixed to the ground pad 41 by, for example, reflow soldering. This installs the stud member 42 to the circuit board 24. The fixing of the stud member 42 can be performed simultaneously with, for example, a process of mounting the connector 30 and other components onto the circuit board 24 by reflow soldering.

The outer shape of the ground pad 41 may be substantially similar to the outer shape of the flange 42a, i.e., substantially D-shaped in plan view. Thus, the flange 42a and the ground pad 41 have rotationally asymmetric shapes in plan view. Consequently, in the circuit board 24, when the flange 42a is fixed to the ground pad 41 by reflow soldering, the flange 42a, which is subjected to the surface tension of the heated and melted solder, is always positioned in a predetermined direction of rotation on the ground pad 41. To be specific, the flange 42a is always soldered in the direction of rotation in which the cut surface 42a1 coincides with the linear portion of the ground pad 41. As a result, the support structure 40 can always have the arm part 48 of the capture member 44, which will be described later, disposed on the opposite side from the connector 30, thus improving the manufacturing efficiency and the assembly efficiency of the electronic modules 32, 33.

The screw 43 is a metal screw having a head portion 43a that has an outer shape which is substantially the same as that of the flange 42a, and a screw portion 43b that can be screwed into the screw hole 42b1. An operation hole 43a1 is formed at the center of the head portion 43a. The operation hole 43a1 is a cross hole into which a tool such as, for example, a Phillips head screwdriver is fitted to perform a rotational operation. The screw 43 may be provided with a shaft portion 43c, which has no thread formed thereon, at the base of the screw portion 43b relative to the head portion 43a. The shaft portion 43c may be formed to have a diameter that is slightly smaller than, for example, the outer diameter (nominal diameter) of the screw portion 43b.

The capture member 44 is a metal component having a stud connection part 46, a screw holding part 47, and an arm part 48. The capture member 44 is a holding member for connecting the screw 43 to the stud member 42 in a state in which the screw 43 can be fastened into the screw hole 42b1. The capture member 44 is, for example, a stainless sheet metal component. The capture member 44 is elastically deformable as a whole between a substantially L-shape (refer to FIG. 3A) and a substantially U-shape (refer to FIG. 3C) in a side view.

The stud connection part 46 is a part connected to the stud member 42. The stud connection part 46 has a hole 46a and a plurality of protrusions 46b, and is shaped like a thin ring. The hole 46a has an inner diameter that is larger than the outer diameter of the cylindrical body 42b, and allows the cylindrical body 42b to be inserted therein. The protrusions 46b are plate pieces that protrude from the inner circumference of the hole 46a toward the center. The protrusions 46b may have, at the tips thereof, claw-shaped portions curved toward the Z2 side. The protrusions 46b are arranged at predetermined intervals in the circumferential direction of the hole 46a. A gap G is formed between two protrusions 46b, 46b on the opposite side from the arm part 48 in the diameter direction of the hole 46a, the gap G being slightly wider than the gaps between other protrusions 46b and 46b. The stopper portion 42b2 of the cylindrical body 42b is placed in the gap G.

The screw holding part 47 is a part adapted to hold the screw 43 in a relatively rotatable state. The screw holding part 47 has a hole 47a, and is shaped like a thin ring. The outer shape of the screw holding part 47 may have the same outer shape as that of the head portion 43a of the screw 43, or may be slightly larger or smaller than the outer shape of the head portion 43a. The screw 43 has a shaft portion 43c relatively rotatably engaged with the hole 47a so as to be prevented from slipping off. Therefore, the hole 47a allows the screw portion 43b to be inserted therein, but must not allow the inserted screw portion 43b to easily come off. For this reason, the inner diameter of the hole 47a is slightly smaller than the outer diameter of the screw portion 43b. If the screw 43 does not have the shaft portion 43c, the screw holding part 47 may have the hole 47a moved all the way to the base of the screw portion 43b, and hold the screw 43 there in a relatively rotatable manner.

The arm part 48 is a curved portion that connects the stud connection part 46 and the screw holding part 47, and is an elastically deformable leaf-spring-like member. The capture member 44 of the present embodiment is a sheet metal component punched out of a metal plate by a press or the like. Hence, one end of the arm part 48 is formed integrally with the stud connection part 46, and the other end thereof is formed integrally with the screw holding part 47. There are no limitations on the length of the arm part 48 or the opening/closing angle at which the arm part 48 can be elastically deformed. However, the arm part 48 must smoothly move at least the screw 43 held by the screw holding part 47 between a position where the screw 43 can be fastened into the screw hole 42b1 (refer to FIG. 3C and FIG. 4A) and a position where the screw 43 does not interfere with the attaching and detaching operations of the electronic module 32 (33) (refer to FIG. 3B and FIG. 4C).

According to a procedure for assembling the capture member 44, first, the cylindrical body 42b is inserted into the hole 46a of the stud connection part 46 (refer to FIG. 3A and FIG. 3B). At this time, in the stud connection part 46, the cylindrical body 42b is inserted into the hole 46a while the protrusions 46b are spread by the enlarged diameter portion 42b3. At this time, the stopper portion 42b2 is placed in the gap G. Thus, the stud connection part 46 is attached to the cylindrical body 42b in such a manner as to be relatively movable in an axial direction (a ZZ direction) of the cylindrical body 42b between the enlarged diameter portion 42b3 and the flange 42a. Meanwhile, the screw 43 is passed through the hole 47a and held by the screw holding part 47 before or after the operation of connecting the stud connection part 46 to the stud member 42.

Thus, the capture member 44 holding the screw 43 is connected to the stud member 42 in such a manner as to be vertically movable with respect to the stud member 42 (refer to FIG. 3B to FIG. 4B). At this time, the stud connection part 46 has the protrusions 46b on both sides, which form the gap G, locked by the stopper portion 42b2. This restricts the relative rotation of the stud connection part 46 with respect to the cylindrical body 42b. The stopper portion 42b2 also has a function for guiding the vertical movement of the stud connection part 46.

The electronic modules 32, 33 are card type module components that can be connected to the connectors 30 complying with the M.2 standard as described above.

The electronic module 32 is, for example, a storage device. The electronic module 32 of the present embodiment is an SSD (Solid State Drive). As illustrated in FIG. 2, the electronic module 32 has a module substrate 32a, a terminal 32b formed on one end 32a1 of the module substrate 32a, and a semiconductor chip 32c mounted on the module substrate 32a. In the electronic module 32, with the terminal 32b connected to the connector 30, the other end 32a2 of the module substrate 32a is pressed in a Z-direction by the support structure 40. Thus, the electronic module 32 is attached to the circuit board 24. A semicircular cutout 32d, in which the cylindrical body 42b of the stud member 42 can be placed, is formed at the center in the lengthwise direction of the other end 32a2 (refer to FIG. 4C).

The module substrate 32a has ground portions 32e and 32f provided on one surface 32a3 and the other surface 32a4, respectively (refer to FIG. 4A). The ground portions 32e and 32f are metal patterns provided on the periphery of the cutout 32d, and are, for example, copper foil printed by a silk screen process.

The electronic module 33 is, for example, a communication module. The electronic module 33 of the present embodiment is compatible with WWAN (Wireless Wide Area Network). The communication standard with which the electronic module 33 complies may be, for example, WLAN (Wireless Local Area Network) or the like. As illustrated in FIG. 2, the electronic module 33 has a module substrate 33a, a terminal 33b formed on one end 33a1 of the module substrate 33a, and a semiconductor chip 33c mounted on the module substrate 33a. In the electronic module 33, with the terminal 33b connected to the connector 30, the other end 33a2 of the module substrate 33a is pressed in the Z-direction by the support structure 40. Thus, the electronic module 33 is attached to the circuit board 24. A semicircular cutout 33d, in which the cylindrical body 42b of the stud member 42 can be placed, is formed at the center in the lengthwise direction of the other end 33a2.

Ground portions 33e and 33f similar to the ground portions 32e and 32f are provided also on one surface 33a3 and the other surface 33a4, respectively, of the module substrate 33a (refer to the parenthesized symbols in FIG. 4A). The ground portions 33e and 33f are also metal patterns provided on the periphery of the cutout 33d, and are, for example, copper foil printed by a silk screen process.

The other end 33a2 of the electronic module 33 is provided with a plurality of connection portions 33g. Cables 51 from antenna elements 50 installed at various locations on the chassis 12 or the cover body 11 are connected as appropriate to the connection portions 33g. In the configuration example illustrated in FIG. 2, a total of six cables 51 are connected to the electronic module 33. Therefore, a total of six connection portions 33g are arranged in parallel, extending over the cutout 33d.

A description will now be given of the operation of attaching and detaching the electronic modules 32, 33 to and from the circuit board 24. Here again, although the operation of attaching and detaching the one electronic module 32 will be representatively described, the operation of attaching and detaching the other electronic module 33 can be performed in the same or similar manner.

First, to mount the electronic module 32 on the circuit board 24, the screw 43 is removed from the screw hole 42b1, and the arm part 48 is opened to move the screw 43 away from the stud member 42 (refer to FIG. 3B). After the terminal 32b of the electronic module 32 is connected to the connector 30, the other end 32a2 thereof is placed immediately beside the cylindrical body 42b. At this time, the stud connection part 46 is placed around the cylindrical body 42b. Thus, when the cylindrical body 42b is placed in the cutout 32d, the other surface 32a4 of the electronic module 32 is placed on the surface of the stud connection part 46 on the Z2 side.

Subsequently, the arm part 48 is elastically deformed to fasten the screw 43 into the screw hole 42b1 from above the electronic module 32. This causes the head portion 43a to push down the other end 32a2 of the electronic module 32 in the Z1 direction via the screw holding part 47. At this time, the stud connection part 46 of the support structure 40 moves also to the Z1 side along the axial direction of the cylindrical body 42b. This prevents the arm part 48 from being subjected to excessive load in the closing direction and consequently damaged or elastically deformed. It is also possible to suppress the falling of the screw 43 off the screw holding part 47. When the screw 43 has been completely fastened, the other end 32a2 of the electronic module 32 is supported by the screw 43 and the screw holding part 47. This completes the operation of attaching the electronic module 32 to the circuit board 24 (refer to FIG. 3C and FIG. 4A).

Next, to remove the electronic module 32 from the circuit board 24, the screw 43 is loosened (refer to FIG. 4B). This causes the pressing force applied by the screw 43 to the electronic module 32 to be gradually released, so that the electronic module 32 is subjected to an urging force at the connection between the connector 30 and the terminal 32b, and the other end 32a2 rises to the Z2 side with the one end 32a1 acting as the pivot point. In other words, the other end 32a2 moves to the Z2 side along with the screw 43. At this time, the stud connection part 46 of the support structure 40 also moves to the Z2 side along the axial direction of the cylindrical body 42b. This prevents the arm part 48 from being subjected to excessive load in the opening direction and consequently damaged or elastically deformed. It is also possible to suppress the falling of the screw 43 off the screw holding part 47. When the removal of the screw 43 is completed, the screw 43 moves away from the other end 32a2 due to the elastic force of the arm part 48 (refer to FIG. 3B and FIG. 4C). This makes it easy to detach the electronic module 32 from the circuit board 24.

As described above, the support structure 40 of the present embodiment includes the stud member 42, the screw 43, and the capture member 44 made of metal. The capture member 44 has a stud connection part 46 connected to the stud member 42, the screw holding part 47 that holds the screw 43 in a relatively rotatable state, and the elastically deformable arm part 48 that connects the stud connection part 46 and the screw holding part 47.

Thus, the screw 43 of the support structure 40 is always captured, via the capture member 44, by the stud member 42 fixed to the circuit board 24. Therefore, the support structure 40 is capable of preventing the screw 43 from falling into the chassis 12 or being lost while attaching or detaching the electronic modules 32, 33, thus leading to improved workability. In addition, the capture member 44 can be installed later to the stud member 42 fixed to the circuit board 24, making the capture member 44 highly versatile. Further, the capture member 44, which is made of metal, does not affect the ground of the electronic modules 32, 33 despite being interposed between the screw 43 and the stud member 42 and the electronic modules 32, 33. In addition, the electronic apparatus 10 provided with the circuit board 24 that supports the electronic modules 32, 33 by the support structure 40 described above can reduce the risk of the screws 43 falling off or being lost not only during operations in a factory or the like, but also when the electronic modules 32, 33 are, for example, replaced by a user himself or herself. This improves maintainability and expandability.

The electronic modules 32, 33 of the present embodiment have ground portions (first ground portions) 32e, 33e on the one surfaces 32a3, 33a3 of the other ends 32a2, 33a2. The screw holding part 47 contacts the ground portions 32e, 33e. More specifically, in the support structure 40, the screw holding part 47 interposed between the stud member 42 fixed to the ground pad 41 and the screw 43 fastened to the stud member 42 contacts the ground portions 32e, 33e. For example, if the electronic module 32 is a storage device, then only the one surface 32a3 is normally provided with the ground portion 32e. In such an electronic module 32, the support structure 40 can securely electrically connect the ground portion 32e to the ground pad 41.

In the support structure 40, the outer peripheral surface of the cylindrical body 42b may be provided with a stopper portion 42b2, which restricts the relative rotation of the capture member 44 with respect to the cylindrical body 42b, by locking the protrusions 46b of the stud connection part 46. This makes it possible to control the rotational posture of the capture member 44 (the arm part 48) in a fixed direction when the capture member 44 is attached to the stud member 42. More specifically, in the capture member 44, the arm part 48 can be always placed on the opposite side from the other ends 32a2, 33a2 of the electronic modules 32, 33. With this arrangement, in the support structure 40, the interference of the arm part 48 with the electronic modules 32, 33 is avoided, permitting smooth opening and closing of the arm part 48 and smooth attaching and detaching of the electronic modules 32, 33. The above description has illustrated the configuration in which the two electronic modules 32, 33 are mounted, and supported by the support structure 40. However, the electronic apparatus 10 (the circuit board 24) may have only one of the electronic modules 32 and 33 mounted thereon, or have other types of electronic modules mounted thereon. Further, the support structure 40 may be applied only to a part of an electronic module mounted, and the remaining electronic modules may be supported by other structures.

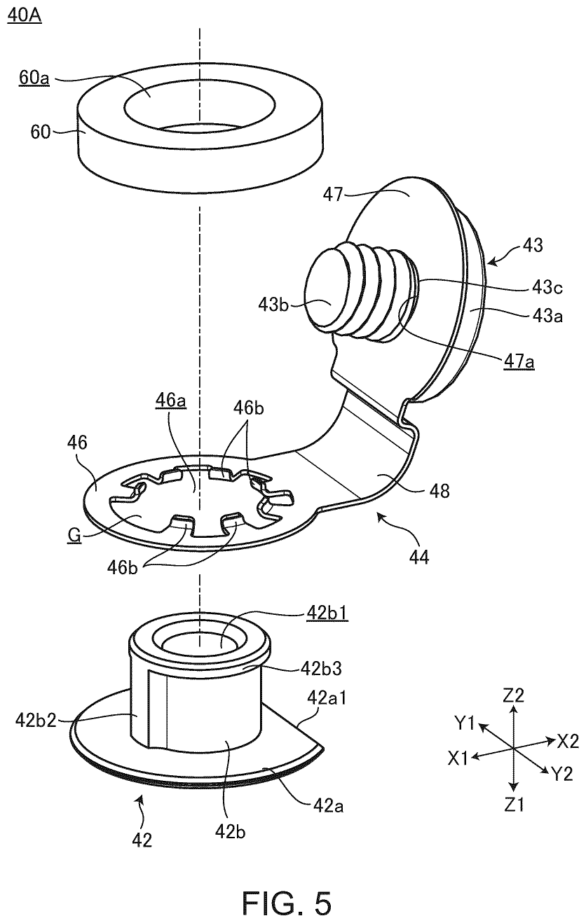

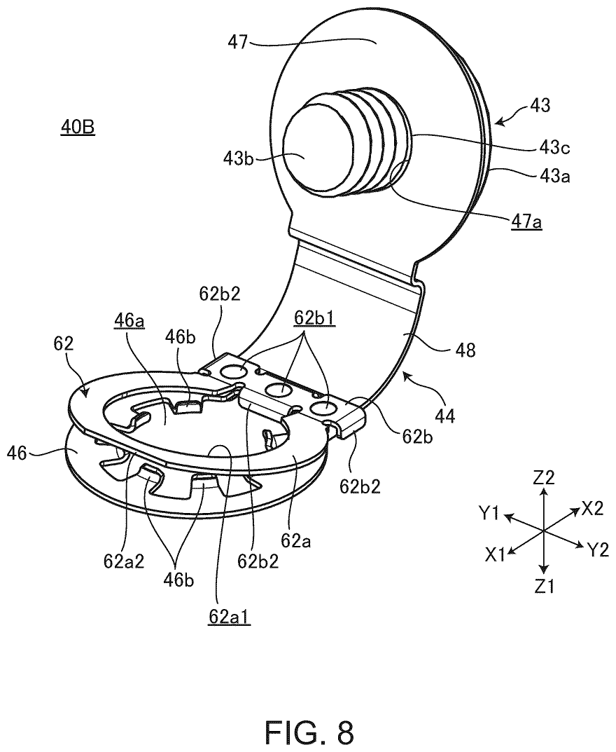

FIG. 5 to FIG. 7 are explanatory diagrams of a support structure 40A according to a first modified example. In FIG. 5 to FIG. 7, symbols that are the same as those shown in FIG. 1 to FIG. 4C denote the same or similar components, and therefore detailed descriptions will be omitted, as the components have the same or similar functions and effects. The same applies to the subsequent FIG. 8 to FIG. 13B.

As described above, in the capture members 44, the screw holding parts 47 contact the ground portions 32e, 33e of the one surfaces 32a3, 33a3 of the electronic modules 32, 33 mounted on the circuit board 24 (refer to FIG. 4A). Here, the electronic modules 32, 33 of the present embodiment may have the ground portions (the second ground portions) 32f, 33f also on the other surfaces 32a4, 33a4 of the other ends 32a2, 33a2 (refer to FIG. 4A). In particular, the electronic module 33, which is a communication module complying with the WWAN standard, for example, requires both-surface ground. In this case, it is difficult for the support structures 40 to make the stud connection parts 46 stably contact with the ground portions 32f, 33f on the other surfaces 32a4, 33a4 of the electronic modules 32, 33. This is because, if the support structures 40 are configured such that the electronic modules 32, 33 are tightly fastened by the screws 43 to firmly hold the electronic modules 32, 33 between the screws 43 (the screw holding parts 47) and the stud connection parts 46, then there is a concern that the electronic modules 32, 33 may be damaged or malfunction.

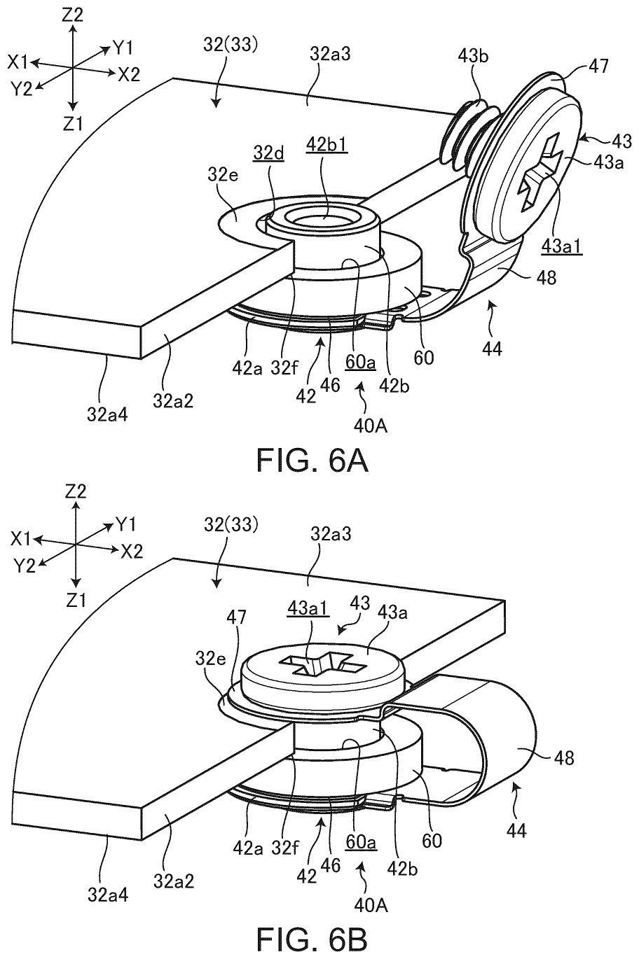

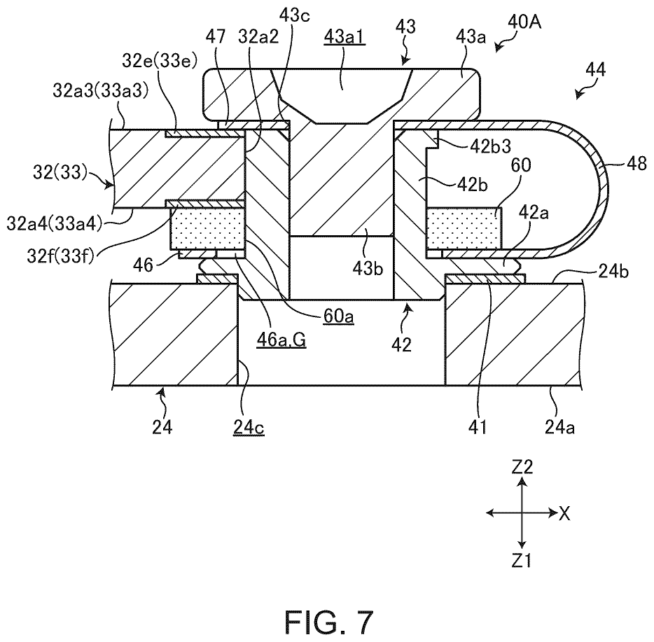

Therefore, the support structure 40A illustrated in FIG. 5 to FIG. 7 has a gasket 60, which is an electrically conductive member. The gasket 60 is made of, for example, an electrically conductive cushion material. The gasket 60 is formed like, for example, a ring having a predetermined thickness. The gasket 60 is placed on the Z2 side relative to a stud connection part 46, with a cylindrical body 42b inserted into a hole 60a at the center thereof. As illustrated in FIG. 6A to FIG. 7, the gasket 60 is held between an electronic module 32 (33) and a stud connection part 46 so as to be in contact with these two components. In other words, the gasket 60 contacts a ground portion 32f (33f) and the stud connection part 46. This allows the support structure 40A to provide electrical connection between the ground portion 32f (33f) and a stud member 42.

FIG. 8 to FIG. 10 are explanatory diagrams of a support structure 40B according to a second modified example.

The support structure 40B illustrated in FIG. 8 to FIG. 10 is different from the support structure 40A illustrated in FIG. 5 to FIG. 7 in that a leaf spring member 62 made of metal replaces the gasket 60 as the electrically conductive member. The leaf spring member 62 is, for example, a stainless sheet metal component. The leaf spring member 62 is attached to a capture member 44 as one piece. The leaf spring member 62 has a ring portion 62a and a fixed portion 62b. FIG. 8 does not illustrate a stud member 42 constituting the support structure 40B, and illustrates only the capture member 44.

The ring portion 62a has a hole 62a1 at the center thereof. A cylindrical body 42b is inserted in the hole 62al. The outer peripheral end surface of the ring portion 62a on the opposite side (the X1 side) from the fixed portion 62b side is cut at a cut surface 62a2. Thus, the ring portion 62a has a substantially D-shape in plan view.

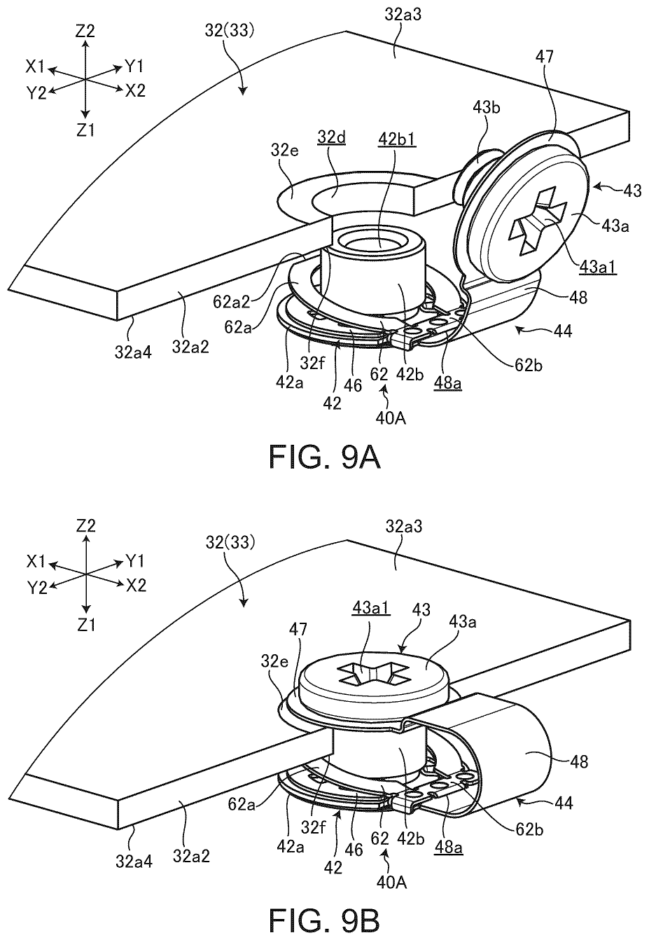

The fixed portion 62b is a portion fixed to the capture member 44. The fixed portion 62b is a plate-like member, and is formed integrally with the outer peripheral end surface of the ring portion 62a on the opposite side from the cut surface 62a2 side. The fixed portion 62b is fixed to the surface of the base portion of the arm part 48 on the Z2 side relative to the stud connection part 46 by, for example, spot welding. The fixed portion 62b has a plurality of positioning holes 62b1 and a plurality of positioning pieces 62b2. The positioning holes 62b1 can be used to set the fixing position of the fixed portion 62b in relation to the capture member 44. The positioning pieces 62b2 are plate pieces formed by, for example, bending the peripheral edge of the fixed portion 62b to the Z1 side. The positioning pieces 62b2 are disposed so as to engage with both side edges of an arm part 48, an engagement hole 48a formed in the arm part 48 (refer to FIG. 9A), and the inner peripheral wall of a hole 46a. This allows the positioning pieces 62b2 to prevent the fixed portion 62b from being displaced in relation to the capture member 44.

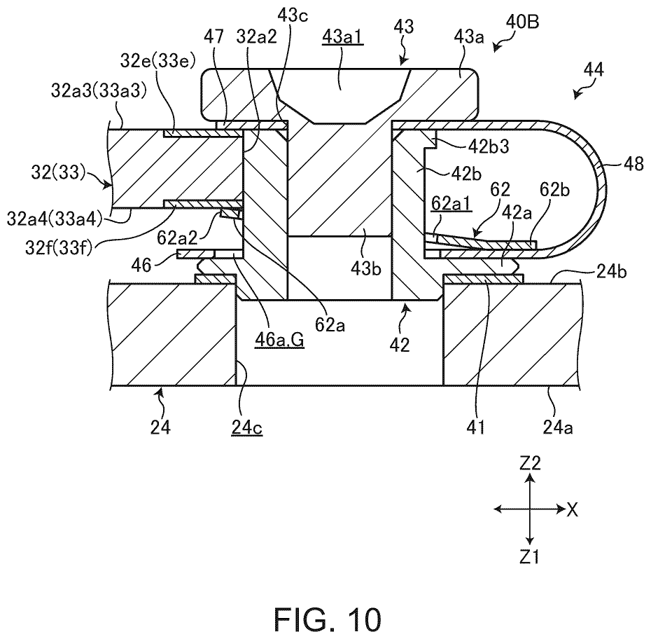

The ring portion 62a is in an inclined posture, gradually tilting to the 22 side from the base (the fixed portion 62b), which is fixed to the arm part 48, toward the tip (the cut surface 62a2). Therefore, the area between the fixed portion 62b and the ring portion 62a is slightly bent. The ring portion 62a is disposed on the Z2 side relative to the stud connection part 46, with the cylindrical body 42b inserted in the hole 62al. When a screw 43 is fastened to the stud member 42, the ring portion 62a of the leaf spring member 62 is held between an electronic module 32 (33) and the stud connection part 46 and comes in contact with a ground portion 32f (33f) (refer to FIG. 9B and FIG. 10). The ring portion 62a of the leaf spring member 62 is pressed by the ground portion 32f (33f) and elastically displaced, thus further securely being pressed against the ground portion 32f (33f).

Consequently, the support structure 40B can also provide electrical connection between the ground portion 32f (33f) and the stud member 42. Further, the tip of the ring portion 62a is provided with the cut surface 62a2. This allows the ring portion 62a to come in contact with the ground portion 32f (33f) by line rather than point, thereby ensuring further stable electrical connection.

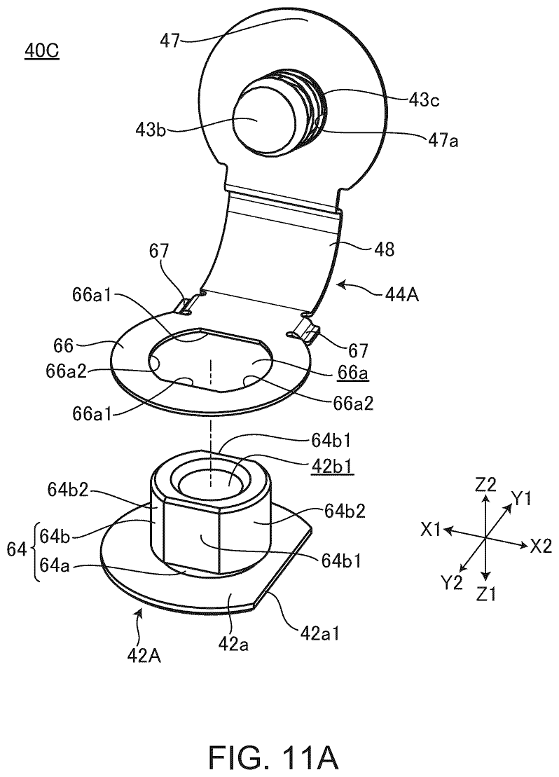

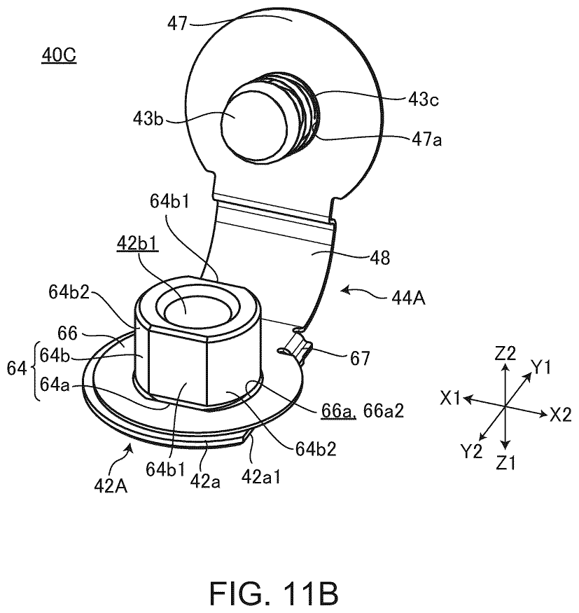

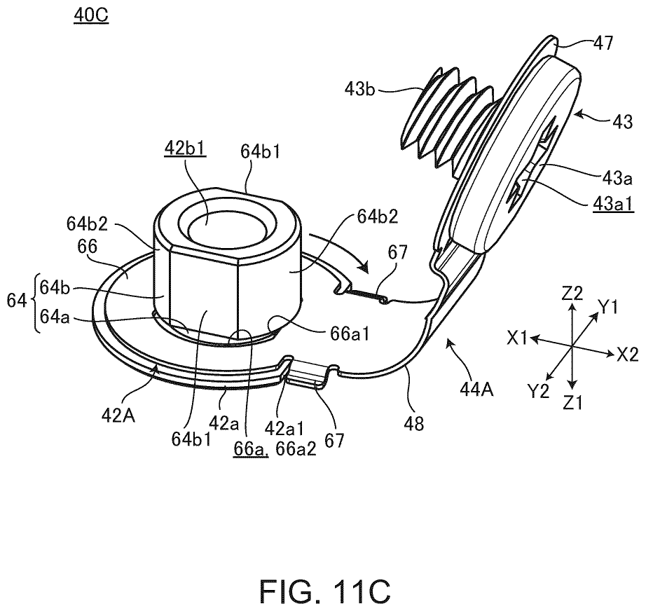

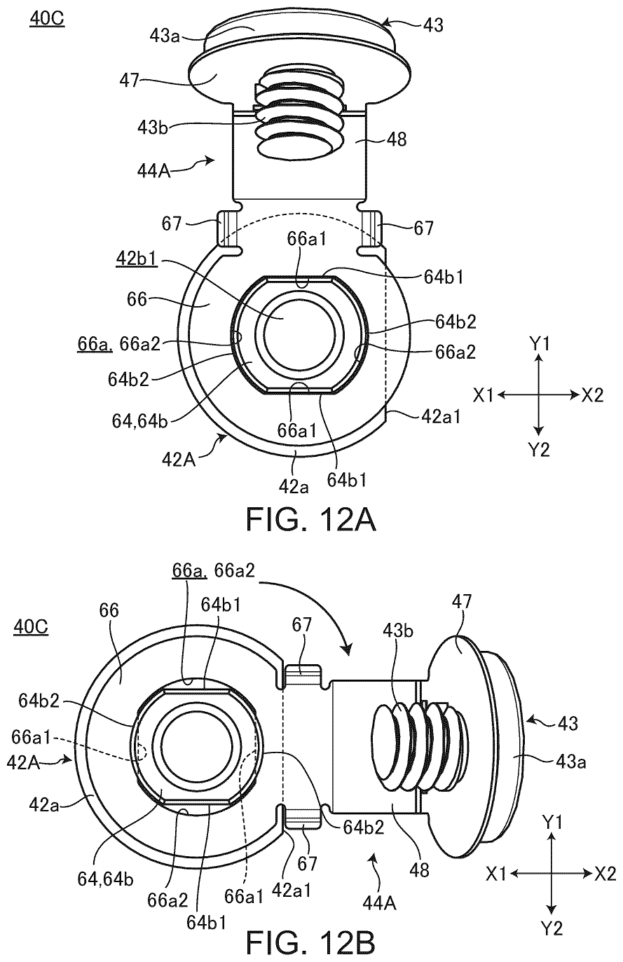

FIG. 11A to FIG. 12B are explanatory diagrams of a support structure 40C according to a third modified example.

The support structure 40C illustrated in FIG. 11A to FIG. 12B includes a stud member 42A and a capture member 44A, which have different configurations from those of the stud members 42 and the capture members 44 of the support structures 40, 40A, and 40B described above. More specifically, in the capture member 44 described above, the protrusions 46b of the stud connection part 46 are locked by the stopper portion 42b2 of the cylindrical body 42b. This restricts the relative rotation of the capture member 44 with respect to the stud member 42 thereby controlling the rotational posture of the arm part 48, which has been attached to the stud member 42, in a fixed direction. On the other hand, the support structure 40C has a configuration that replaces the stopper portion 42b2 and the protrusions 46b.

The stud member 42A has a cylindrical body 64 having a different configuration from the above-described cylindrical body 42b. The cylindrical body 64 has a first portion 64a provided on a base side, rising from a flange 42a, and a second portion 64b provided on a tip side in the rising direction. The cylindrical body 64 has a stepped rod shape with a smaller diameter on the base side (the first portion 64a) than on the tip side (the second portion 64b).

The first portion 64a is cylindrical or columnar. The height of the first portion 64a in the Z-direction is considerably smaller than that of the second portion 64b, and slightly larger than the thickness of a stud connection part 66 of the capture member 44A.

The second portion 64b is provided continuously on the Z2 side relative to the first portion 64a. The second portion 64b has a cylinder with a larger diameter than that of the first portion 64a, and has a pair of flat surface portions 64b1, 64b1 formed on the outer peripheral surface thereof. The flat surface portions 64b1 are parallel to each other and extend in the axial direction (the Z-direction) of the cylindrical body 64. Thus, the second portion 64b has a substantially elliptical shape with the minor axis side formed by straight lines (the flat surface portions 64b1) in plan view. In other words, the outer peripheral surface of the second portion 64b is formed of two flat surface portions 64b1 and two curved surface portions 64b2. The linear distance between the pair of flat surface portions 64b1, 64b1 is equal to or slightly smaller than the outer diameter of the first portion 64a.

The capture member 44A has a stud connection part 66 of a different configuration from the stud connection part 46 described above. Further, the capture member 44A has the pair of stopper parts 67, 67 at the base of the arm part 48 relative to the stud connection part 66d.

The stud connection part 66 has a hole 66a, and is shaped like a thin ring. The hole 66a is similar to the outer shape of the second portion 64b of the cylindrical body 64 and has an outer shape slightly larger than the second portion 64b. In other words, the hole 66a has a substantially elliptical shape with the minor axis side formed by a pair of linear portions 66a1, 66a1 in plan view. This means that the inner peripheral surface of the hole 66a is formed of the two linear portions 66a1 and two arcuate portions 66a2. This allows the second portion 64b to be inserted into the hole 66a without any rattling. Meanwhile, the hole 66a is relatively rotatable about the axis thereof with respect to the first portion 64a.

The stopper parts 67 are formed on both sides of the base of the arm part 48 relative to the stud connection part 66. Each of the stopper parts 67 is a crank-shaped plate piece that protrudes in a direction (outward) away from the edge of the arm part 48 in a width direction, is bent once to the Z1 side, and then is bent outward again.

According to a procedure for assembling the capture member 44A, first, the second portion 64b of the cylindrical body 64 is inserted into the hole 66a of the stud connection part 66 (refer to FIG. 11A, FIG. 11B, and FIG. 12A). At this time, the hole 66a allows the second portion 64b to pass therethrough and is pressed down to the position where the hole 66a engages with the first portion 64a. This causes the stopper parts 67 to come in contact with the surface of the flange 42a on the Z2 side so as to be pressed.

Subsequently, the capture member 44A (the stud connection part 66) is rotated by a predetermined angle about the axis of the first portion 64a. The angle of the rotation is 90 degrees if the direction of the rotation is a direction that allows the stopper parts 67 to reach a cut surface 42a1 of the flange 42a with a shortest distance, or 270 degrees in the case of the opposite direction therefrom. Thus, as illustrated in FIG. 11C and FIG. 12B, the linear portions 66a1 of the hole 66a are placed directly below the curved portions 64b2 of the second portion 64b. This prevents the stud connection part 66 from slipping off the cylindrical body 64 in the Z-direction, with the second portion 64b acting as the stopper. At the same time, the stopper parts 67 fall off the surface of the flange 42a on the Z2 side, drop to the Z1 side, and come in contact with a cut surface 42al.

As described above, the stopper parts 67 of the stud connection part 66 are locked by the flange 42a (the cut surface 42a1), thereby restricting further relative rotation about the axis of the cylindrical body 64. As a result, the capture member 44A is attached to the stud member 42A, with the arm part 48 facing in a predetermined rotational direction, that is, in a rotated posture facing in the direction opposite from the connector 30 side.

Therefore, the capture member 44A of the support structure 40C can also always place the arm part 48 on the opposite side from the other ends 32a2, 33a2 of the electronic modules 32, 33. Thus, in the support structure 40C also, the interference of the arm part 48 with the electronic modules 32, 33 is avoided, permitting smooth opening and closing of the arm part 48 and smooth attaching and detaching of the electronic modules 32, 33. Further, as compared with the above-described stud member 42, the stud member 42A eliminates the need for the stopper portions 42b2, permitting the configuration of a simpler shape. Similarly, compared with the above-described stud connection part 46, the stud connection part 46A eliminates the need for the protrusions 46b, permitting the configuration of a simpler shape. As a result, the manufacturing cost of the support structure 40C can be reduced as compared with the support structure 40 and the like described above.

The capture member 44A does not vertically move in the axial direction with respect to the cylindrical body 64. For this reason, the amount of deformation of the arm part 48 of the capture member 44A may be set to be larger than that of the capture member 44. This makes it possible also for the capture member 44A to suppress damage to the arm part 48 and falling off or the like of the screw 43 from the screw holding part 47, thus ensuring smooth operation of the screw 43.

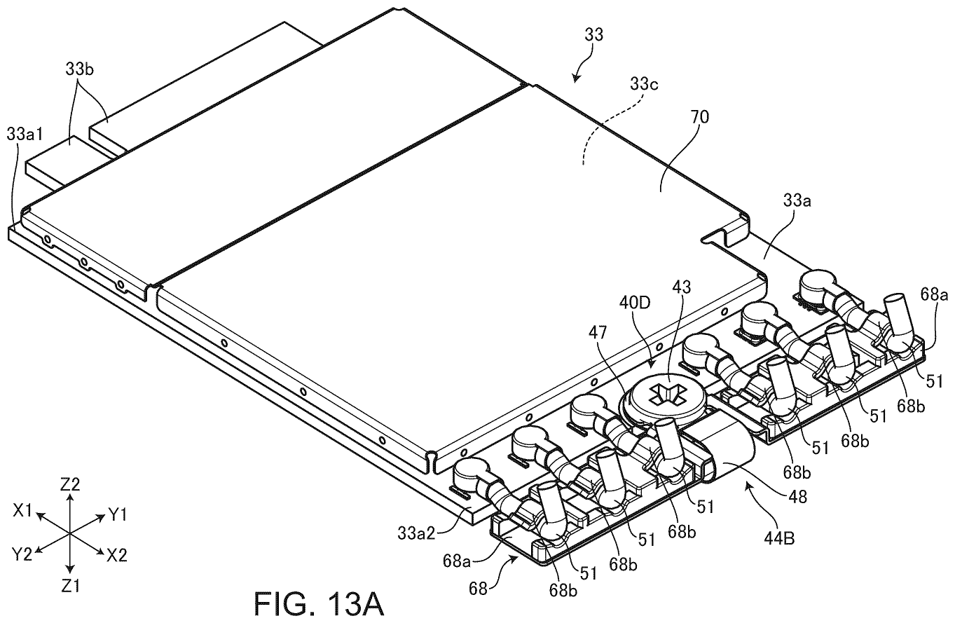

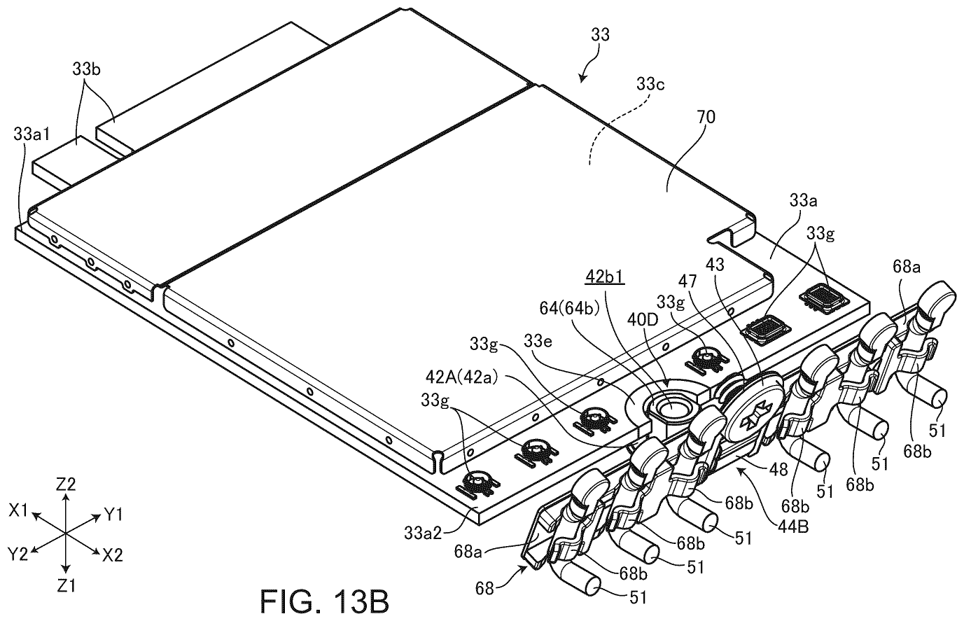

FIG. 13A and FIG. 13B are explanatory diagrams of a support structure 40D according to a fourth modified example.

The support structure 40D illustrated in FIG. 13A and FIG. 13B is different from the support structure 40C illustrated in FIG. 11A to FIG. 12B in that the support structure 40D includes a capture member 44B configured to provide a screw holding part 47 with a cable guide 68. The cable guide 68 is a guide member that holds an end portion of a cable 51 connected to a connection portion 33g of an electronic module 33. Symbol 70 in FIG. 13A and FIG. 13B denotes a heatsink covering a semiconductor chip 33c of the electronic module 33.

The cable guide 68 is composed of guide plates 68a integrally formed on both sides of a screw holding part 47. The guide plates 68a are provided like wings protruding from the screw holding part 47 along the longitudinal direction of the other end 33a2. Each of the guide plates 68a has, for example, a plurality of clips 68b formed thereon. In an electronic apparatus 10 of the present embodiment, a total of six cables 51 are connected to the electronic module 33. Therefore, the cable guide 68 has three clips 68b on each of the guide plates 68a, totaling six clips 68b.

Thus, in the support structure 40D, at the time of attaching or detaching the electronic module 33, when the screw 43 is removed from a screw hole 42b1 and an arm part 48 is opened, the cable guide 68 also moves to open or close integrally with the screw holding part 47. Therefore, when the cables 51 are detached from the connection portions 33g, the corresponding relationships between the cables 51 and the connection portions 33g are prevented from being mixed up. Further, also when connecting the cables 51 to the connection portions 33g, the predetermined cables 51 and connection portions 33g can be accurately and easily connected. As a result, the support structure 40D improves the operation efficiency for attaching and detaching between the antenna elements 50 and the electronic module 33. In addition, the capture member 44B can also be installed later to a stud member 42A fixed to the circuit board 24, making the capture member 44B highly versatile.

The support structure 40D illustrated in FIG. 13A and FIG. 13B illustrates a configuration in which the capture member 44A of the support structure 40C illustrated in FIG. 11A to FIG. 12B is provided with the cable guide 68. However, the cable guide 68 may be applied to the remaining support structures 40, 40A, and 40B.

It should be noted that the present invention is not limited to the embodiments described above, but can of course be freely modified within the range not deviating from the gist of the present invention.

### DESCRIPTION OF SYMBOLS

10 electronic apparatus
12 chassis
24 circuit board
30 connector
32, 33 electronic module
32e, 32f, 33e, 33f ground portion
40, 40A to 40D support structure
42, 42A stud member
42a flange
42b, 64 cylindrical body
43 screw
44, 44A, 44B capture member
46, 66 stud connection part
47 screw holding part
48 arm part
50 antenna element
51 cable
60 gasket
62 leaf spring member
68 cable guide

What is claimed is:

1. A support structure supporting, on a circuit board, one end of an electronic module having the other end connected to a connector mounted on the circuit board, the support structure comprising:
a stud member having a flange fixed to a surface of the circuit board, and a cylindrical body which has a screw hole formed therein and which rises from the flange;
a screw that supports the other end of the electronic module by being screwed into the screw hole; and
a metal capture member having a stud connection part connected to the stud member, a screw holding part that holds the screw in a relatively rotatable state, and an elastically deformable arm part that connects the stud connection part and the screw holding part.

2. The support structure according to claim 1,
wherein the electronic module has a first ground portion on one surface at the other end thereof, and
the screw holding part contacts the first ground portion.

3. The support structure according to claim 2,
the electronic module having a second ground portion on the other surface opposite from the one surface at the other end, and
further including an electrically conductive member, which is placed between the stud connection part and the electronic module, and contacts the second ground portion.

4. The support structure according to claim 3,
wherein the electrically conductive member is a ring-shaped gasket inserted onto the cylindrical body.

5. The support structure according to claim 3,
wherein the electrically conductive member is a metal leaf spring member fixed to the capture member.

6. The support structure according to claim 1,
wherein the stud connection part is relatively movable with respect to the cylindrical body along an axial direction of the cylindrical body.

7. The support structure according to claim 1,
wherein the stud connection part has a hole into which the cylindrical body is inserted, and a protrusion that protrudes from an inner circumference of the hole, and
an outer circumferential surface of the cylindrical body is provided with a stopper portion that restricts a relative rotation of the capture member with respect to the cylindrical body by locking the protrusion.

8. The support structure according to claim 1,
wherein the stud connection part has a hole into which the cylindrical body is inserted,
the cylindrical body has:
a first portion which is provided on a base side, rising from a flange, and inserted into the hole in a relatively rotatable manner, and
a second portion which is continuously provided at a tip side of the first portion in a direction of rising from the flange, which can be inserted into the hole, and which prevents the stud connection part that has been rotated by a predetermined angle at the first portion from slipping off the cylindrical body, and
the capture member further includes a stopper portion that is locked by the stud member in the case where the stud connection part is rotated by the predetermined angle at the first portion and prevented from slipping off the cylindrical body by the second portion, thus restricting the stud connection part from rotating more than the predetermined angle.

9. The support structure according to claim 1,
wherein the capture member further includes a cable guide which is provided integrally with the screw holding part and which holds a cable connected to the other end of the electronic module.

10. An electronic apparatus comprising:
a circuit board having a connector mounted thereon;
an electronic module having one end thereof connected to the connector; and
a support structure that supports, on the circuit board, the other end of the electronic module,
wherein the support structure has:
a stud member which has a flange fixed to a surface of the circuit board, and a cylindrical body which has a screw hole formed therein and rises from the flange;
a screw that supports the other end of the electronic module by being screwed into the screw hole; and
a metal capture member having a stud connection part connected to the stud member, a screw holding part which holds the screw in a relatively rotatable state, and an elastically deformable arm part which connects the stud connection part and the screw holding part.

11. The electronic apparatus according to claim 10,
wherein the electronic module has a first ground portion on one surface at the other end, and
the screw holding part contacts the first ground portion.

12. The electronic apparatus according to claim 11,
wherein the electronic module has a second ground portion on the other surface opposite from the one surface at the other end, and
an electrically conductive member, which is placed between the stud connection part and the electronic module, and contacts the second ground portion, is included.

13. The electronic apparatus according to claim 10,
wherein the electronic module is a storage device.

14. The electronic apparatus according to claim 10,
the electronic module being a communication module,
further including an antenna element connected by a cable to a connection part provided on the other end of the communication module, and
the capture member further including a cable guide which is provided integrally with the screw holding part to hold the cable.
